(19) United States
(12) Patent Application Publication
(10) Pub. No.: US 2006/0214820 A1
(43) Pub. Date: Sep. 28, 2006

(54) Decoder circuit

(76) Inventors: Richard Petrus Kleihorst, Eindhoven (NL); Victor Emmanuel Stephanus Van Dijk, Eindhoven (NL); Andre Krijn Nieuwland, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/567,691

(22) PCT Filed: Aug. 5, 2004
(86) PCT No.: PCT/IB04/51404

§ 371 Date: Feb. 7, 2006

(30) Foreign Application Priority Data
Aug. 12, 2003 (EP) 03102499.5

(51) Int. Cl. H03M 7/00

(52) U.S. Cl. 341/50; 341/120

(57) ABSTRACT

A decoder circuit, for example a dual-rail decoder, receives input signals (43) from the end of a communications bus (not shown). The parity is calculated over the data wires (Dₒ, D₁, D₂, D₃) using exclusive OR gates (45, 47, and 49). The calculated data parity signal (51) is compared with a transmitted parity signal (53) (shown as “carry”) in an exclusive OR gate (55). Rather than connecting the control signal (57) from the exclusive OR gate (55) directly to the multiplexers (590, 591, 592, 593), the control signal (57) is instead connected to a gating circuit (71). The gating circuit (71), for example a AND gate, receives the control signal (57) as a first input signal. The gating circuit (71) also receives a second input signal in the form of a gating control signal (73). The gating control signal (73) is delayed by a predetermined amount, for example corresponding to the worst case delay of the signals in the input data signals (43). Thus, the gating control signal (73) does not control the gating circuit until such time as all of the data signals are valid, ie until the last transition on the data signal (43) has occurred, thereby preventing glitches and reducing power consumption in the decoder circuit.

### FIELD OF THE INVENTION

The invention relates to a decoder circuit, and in particular, to a low power decoder circuit for a communication bus.

### BACKGROUND OF THE INVENTION

As integrated circuit technology is scaled to provide increased density on a chip, the on-chip interconnects tend to become narrower and narrower. These trends lead to an increase in coupling capacitance with neighbouring wires, which in turn leads to increased interference or crosstalk between wires.

A well known example of such interference is the increase in mutual capacitance (Cm) between neighbouring conductors of data communication devices, such as communication buses. The increase in mutual capacitance not only has a degrading effect on signal integrity, but also increases the overall power consumption of the data communication device. The increase in component density, together with the downscaling of the semiconductor technology dimensions, add to the overall power consumption of an integrated circuit and associated electronic device. In fact, integrated circuit power consumption is increasing to such an extent that meeting the power demands without jeopardizing integrated circuit integrity is becoming a major issue. Therefore, measures to reduce the power consumption of an integrated circuit have become increasingly important.

FIG. 1 shows a schematic illustration of a typical fault-tolerant bus structure 1. The bus structure 1 comprises a communication bus 3 for communicating data between an encoder 5 and a decoder 7. The bus 3 receives output data 9 from the encoder 5, and provides input data 11 to the decoder 7. A common problem with the bus 3 is the unequal flight times for the signals on different wires. In other words, signals on different wires on the communication bus 3 will take different amounts of time to propagate along the communication bus 3. In addition to the flight times varying between different wires on the communication bus, the flight times can also vary for each wire over time.

In a fault-tolerant bus structure such as that shown in FIG. 1, this can result in intermediate data patterns on the input 11 of the decoder 7 containing temporary errors. These errors can cause correction circuitry in the decoder 7 to alternately correct or not correct the data patterns, which in turn can result in glitches on the output 13 of the decoder 7.

The unequal flight times are caused by the capacitance between the bus lines, and the different switching patterns between the various wires on the communication bus 3, ie crosstalk. In addition, the circuitry in the encoder S, (for example parity trees in fault tolerant encoders), can also contribute to the different flight times. FIG. 2 shows a traditional point-to-point connection for a three-wire bus having bus drivers 15a to 15c and bus receivers 17a to 17c. The Figure shows a middle wire, hereinafter referred to as a “victim wire” 19, having neighbouring wires, hereinafter referred to as “aggressor wires” 21, 23. A lateral capacitance Cₗₐₜₑᵣₐₗ exists between the victim wire 19 and each of the aggressor wires 21, 23. The lateral capacitance Cₗₐₜₑᵣₐₗ is dependent on the switching behaviour of the lines, and illustrated by the Miller factors M1 and M2.

Therefore, when the victim wire 19 switches from logic 0 to 1, the moment at which the receiving end switches from 0 to 1 depends on the switching behaviour of the aggressor wires 21, 23.

In a first order approach, five different delay times can be distinguished for the victim wire 19. This is illustrated in the table shown in FIG. 3. Clearly, the capacitance that is “seen” by the driver fluctuates heavily depending on the switching direction or behaviour of the aggressor wires 21, 23. This is especially true because of the fact that the dominating parasitic capacitance of each wire is the mutual capacitance. Knowing that the drive strength of the driver is constant, this fluctuating capacitance directly translates into a fluctuating delay, and also into a fluctuating power.

For example, the fastest switching time (or shortest delay) is experienced when both aggressor wires 21, 23 switch in the same direction as the victim wire 19, as shown in the first row in the table. Conversely, the slowest switching (or longest delay) is experienced when both aggressor wires 21, 23 switch in the opposite direction to the victim wire 19, as shown in the last row of the table.

The flight-time fluctuations mentioned above can have a degrading effect on circuits such as decoders, as will be explained below with reference to FIG. 4.

FIG. 4 shows a traditional dual-rail decoder 40. The input signals 43 are the signals received from the end of a communications bus, and the arrival time of the signals 43 will therefore fluctuate as described above. In a dual-rail decoder 40, the parity is calculated over the data wires (D₀, D₁, D₂, D₃) using a parity tree comprising, for example, exclusive OR gates 45, 47 and 49. The calculated data parity signal 51 (“DATAPAR”) is compared with a transmitted parity signal 53 (shown as “carry”) in an exclusive OR gate 55. Due to the fluctuating arrival times of the input signals D₀, D₁, D₂, D₃ the calculated data parity signal 51 will exhibit glitches. In addition, since the exclusive OR gate 55 compares the data parity signal 51 with the carry signal 53, the control signal 57 that is output from the exclusive OR gate 55 will also exhibit glitches.

The control signal 57 is fed to a plurality of multiplexers 59₀, 59₁, 59₂, 59₃ which act as a correction circuit. Each Multiplexer 59₀, 59₁, 59₂, 59₃ receives a respective input data bit (D₀, D₁, D₂, D₃) and a corresponding copy of the data bit (copy0, copy1, copy2, copy3). The control signal 57 controls whether each multiplexer outputs the data bit or the copy of the data bit. Thus, if the data bit and its copy have different flight times, the output data signals (out0, out1, out2, out3) will also exhibit glitches, which will be fed into the next circuit.

FIGS. 5 and 6 show in greater detail the glitches that can be generated in the correction circuit of the dual-rail decoder shown in FIG. 4. As above, FIG. 5 shows that the correction circuit comprises a parity tree having exclusive OR gates 45, 47 and 49. The exclusive OR gates 45, 47 and 49 receive the input data signals D₀, D₁, D₂, D₃, and produce a data parity signal 51 (DATAPAR). The correction circuit also comprises an exclusive OR gate 55 which compares the data parity signal 51 with a carry signal 53, and produces a control signal 57.

FIG. 6 shows how the data signals D₀, D₁, D₂, D₃ arrive at different times. As a result, the exclusive OR gates 45, 47 generate glitches 67a, 69a, respectively. Consequently, exclusive OR gate 49 also produces glitches 67b, 69b on the data parity signal 51, corresponding to the glitches 67a, 69a. Since the exclusive OR gate 55 compares the data parity signal 51 with the carry signal 53, the exclusive OR gate 55 will also produce glitches 67c, 69c.

It will be appreciated that the glitches shown above all contribute to an unnecessary increase in power consumption in the decoder circuit and in the circuitry thereafter. Similar glitches are also experienced in other types of decoders, for example a hamming decoder. Also, non-fault tolerant codes may suffer from the same problem.

The aim of the present invention is therefore to provide a low power decoder circuit that does not suffer from the disadvantages mentioned above.

### SUMMARY OF THE INVENTION

According to a first aspect of the present invention, there is provided a decoder circuit for a communication bus, the decoder circuit receiving a plurality of data signals from the communication bus, the data signals being susceptible of being received at different times, wherein the decoder circuit comprises:

a correction circuit for correcting one or more of the input signals;

a control signal for controlling the correction circuit;

a gating circuit, the gating circuit arranged in the path of the control signal; and

a gating control signal for controlling the gating circuit such that the control signal for controlling the correction circuit is blocked until a predetermined time.

The invention has the advantage of reducing unwanted glitches in the decoder circuit, thereby reducing power consumption.

According to another aspect of the present invention, there is provided a method of reducing power consumption in a decoder circuit for a communication bus, the decoder circuit receiving a plurality of data signals from the communication bus, the data signals being susceptible of being received at different times, wherein the decoder circuit comprises a correction circuit for correcting one or more of the input signals and a control signal for controlling the correction circuit, wherein the method comprises the steps of providing a gating circuit in the path of the control signal, and controlling the gating circuit with a gating control signal, such that the control signal for controlling the correction circuit is blocked until a predetermined time.

### BRIEF DESCRIPTION OF THE DRAWINGS

For a better understanding of the present invention, and to show more clearly how it may be carried into effect, reference will now be made, by way of example, to the accompanying drawings, in which:

FIG. 1 shows a schematic diagram of a fault-tolerant bus structure according to the prior art;

FIG. 2 shows a schematic illustration of a 3-wire bus system, showing how a victim wire is affected by aggressor wires;

FIG. 3 shows a table illustrating the switching modes in the 3-wire bus system of FIG. 2;

FIG. 4 shows in greater detail a traditional dual-rail decoder circuit, in which the control signal for the correction circuit suffers from glitches;

FIG. 5 shows a simplified explanation of glitches experienced in the decoder of FIG. 4 due to differences in the arrival time of data signals;

FIG. 6 shows a timing diagram illustrating the glitches generated by the circuit of FIG. 5;

FIG. 7 shows a decoder circuit according to a first embodiment of the present invention;

FIG. 8 shows a decoder circuit according to a second embodiment of the present invention;

FIG. 9 shows a decoder circuit according to a third embodiment of the present invention;

FIG. 10 shows a traditional hamming decoder circuit;

FIG. 11 shows a hamming decoder circuit according to another aspect of the present invention.

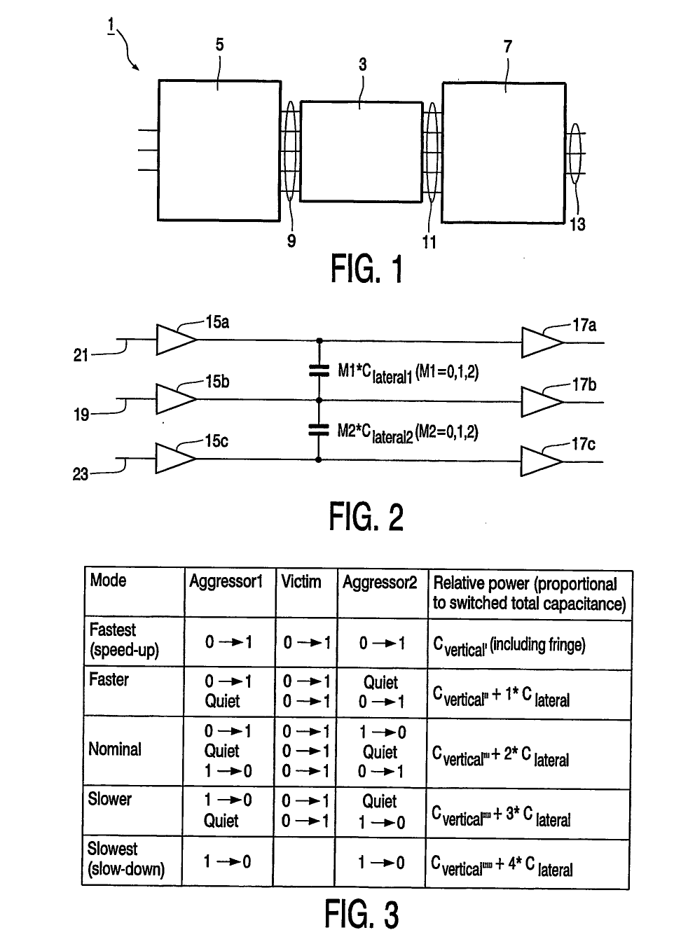

### DETAILED DESCRIPTION OF A PREFERRED EMBODIMENT OF THE PRESENT INVENTION

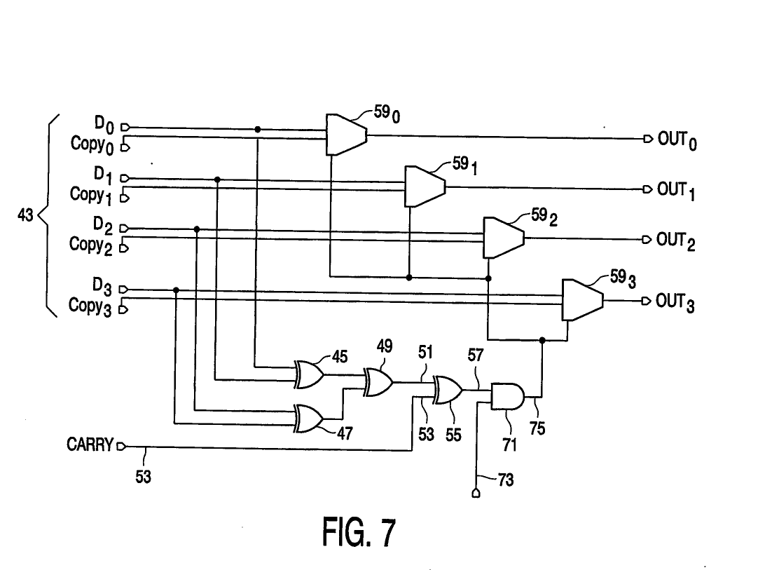

FIG. 7 shows a decoder circuit according to a first embodiment of the present invention. It is noted that, although the preferred embodiments of the invention are described in relation to a dual-rail decoder, it will be appreciated that the invention can equally be applied to other types of decoder circuits.

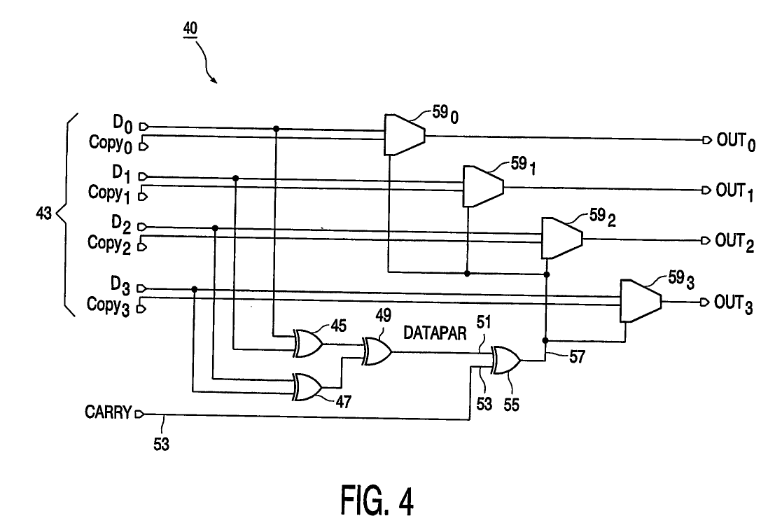

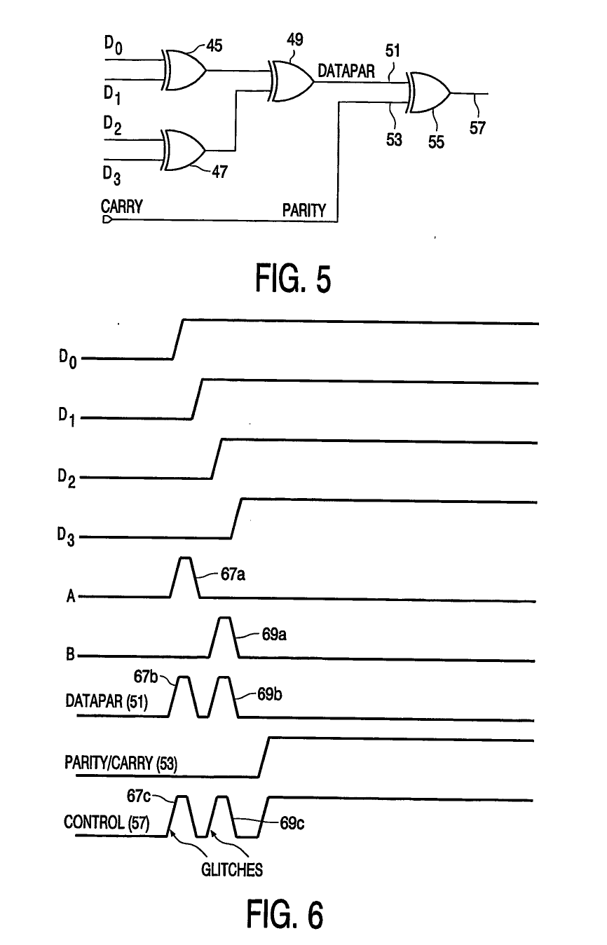

As with the dual-rail decoder shown in FIG. 4, input signals 43 are received from the end of a communications bus (not shown). The parity is calculated over the data wires (D₀, D₁, D₂, D₃) using a parity tree comprising, for example, exclusive OR gates 45, 47 and 49. The calculated data parity signal 51 is compared with a transmitted parity signal 53 (shown as “carry”) in an exclusive OR gate 55.

However, rather than connecting the control signal 57 from the exclusive OR gate 55 directly to the multiplexers 59₀, 59₁, 59₂, 59₃, the control signal 57 is instead connected to a gating circuit 71. The gating circuit 71, for example an AND gate, receives the control signal 57 as a first input signal. The gating circuit 71 also receives a second input signal in the form of a gating control signal 73. The gating control signal 73 is delayed by a predetermined amount. Preferably, the gating control signal is delayed by an amount corresponding to the worst case delay in the input data signals 43. In other words, the gating control signal 73 is delayed by an amount corresponding to the worst flight time of the signals on the communication bus.

Thus, the gating control signal 73 does not control the gating circuit until such time as all of the data signals have become stable, ie until the last transition on the data signal 43 has occurred. As a result, the output signal 75 from the gating circuit 71 is not produced until all the data signals 43 have settled. The output signal 75 is therefore, in effect, a delayed version of the control signal 57.

Preferably, the gating control signal 73 is a delayed version of a system clock signal. However, it will be appreciated that the gating control signal 73 can be generated in other ways.

The delayed control signal 75 is fed to a plurality of multiplexers 59₀, 59₁, 59₂, 59₃, in a similar way to that previously described in FIG. 4 above. The plurality of multiplexers 59₀, 59₁, 59₂, 59₃ act as a correction circuit. Each Multiplexer 59₀, 59₁, 59₂, 59₃ receives a respective input data bit (D₀, D₁, D₂, D₃) and a corresponding copy of the data bit (copy0, copy1, copy2, copy3). The delayed control signal 75 controls each multiplexer such that it outputs the data bit or the copy of the data bit. However, unlike the circuit of FIG. 4, since the delayed control signal 75 is only generated after the input signals are stable, the number of glitches are reduced, thereby reducing the power consumption compared with the circuit of FIG. 4.

The decoder circuit described above therefore has the advantage of consuming less power than the decoder circuit described in FIG. 4.

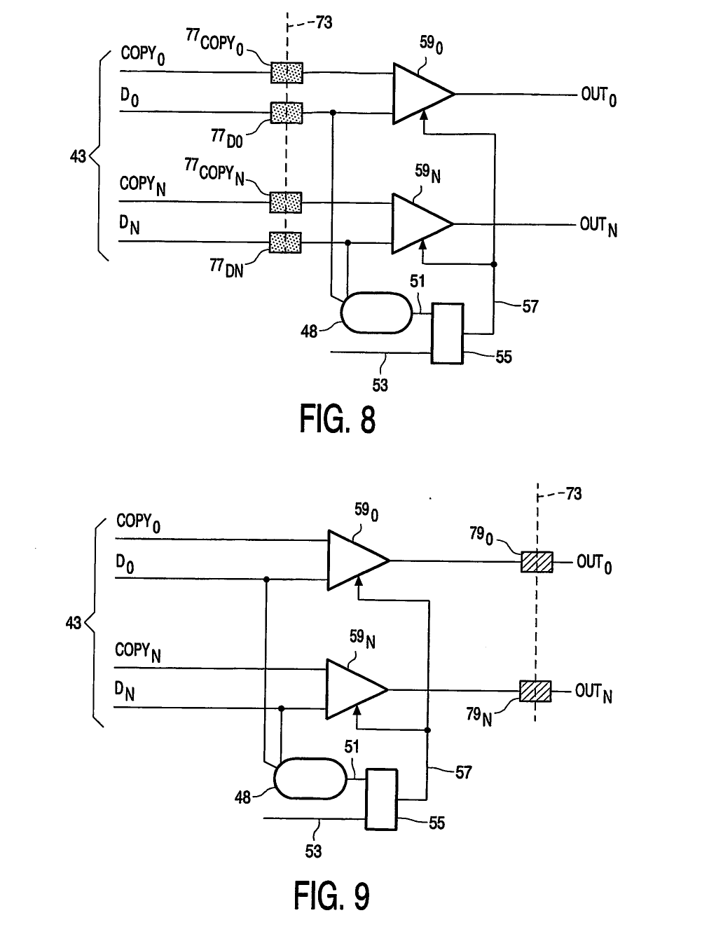

In addition to blocking the control signal for the correction circuit as described above, one or more additional gating circuits can also be provided in the circuit as described below in relation to FIGS. 8 and 9.

FIG. 8 shows a further aspect of the invention in relation to a dual-rail decoder. As with the dual-rail decoder shown in FIG. 4, input signals 43 are received from the end of a communications bus (not shown). The parity is calculated over the data wires (D₀ to D_{N}) using a parity tree 48 (for example having exclusive OR gates 45, 47 and 49 as shown in FIG. 4). The calculated data parity signal 51 is compared with a transmitted parity signal 53 in an exclusive OR gate 55.

The output signal 57 of the exclusive OR gate 55 is fed to the multiplexers 59₀ to 59_{N}, which select either the input data signal D_{N} or the copy of the data signal copyN. If desired, this signal can be gated so that the control signal is blocked until the input signals are stable, as described above in FIG. 7.

According to this embodiment, however, a number of gating circuits 77_{copy0}/77_{D0} to 77_{copyN}/77_{DN} are connected in the path of one or more of the input data signals 43. Each of the gating circuits 77_{copy0}/77_{D0} to 77_{copyN}/77_{DN} is controlled by a gating control signal 73. As with FIG. 7, the gating control signal 73 is generated at a point when the data input signals 43 have become stable. This means that the output data signals from the plurality of gating circuits 77_{copy0}/77_{D0} to 77_{copyN}/77_{DN} are only passed to the parity tree circuit 48 and multiplexers 59₀ to 59_{N} after the gating control signal 73 has declared the input data signals 43 to be valid. In other words, the decoder suppresses the glitches on the data lines received from the communications bus prior to the data signals being decoded.

Although this embodiment requires more gates to suppress glitches compared to the circuit of FIG. 7, (ie in which a single gating circuit 71 was connected to the control signal of the multiplexers), it does have the advantage of reducing glitches in the parity tree circuit 48. Also, the consequence of the spread in transition delay is eliminated at the plurality of gating circuits 77_{copy0}/77_{D0} to 77_{copyN}/77_{DN}, which means that the glitches disappear from the output data signals. This has the advantage of avoiding glitches in any circuitry that follows the decoder circuit. In other words, with the approach shown in FIG. 7, although unnecessary switching at the output between copy-set and data-set is prevented, transitional differences still appear at the output, which can then cause glitch-power dissipation in any subsequent circuits.

FIG. 9 shows a further embodiment of the dual-rail decoder. As with the dual-rail decoder shown in FIGS. 4 and 8, input signals 43 are received from the end of a communications bus (not shown). The parity is calculated over the data wires (D₀ to D_{N}) using a parity tree 48 (for example having exclusive OR gates 45, 47 and 49 as shown in FIG. 4). The calculated parity signal 51 is compared with a transmitted parity signal 53 in an exclusive OR gate 55.

The control signal 57 outputted from the exclusive OR gate 55 is fed to the multiplexers 59₀ to 59_{N}, which select either the input data signal D_{N} or the copy data signal copyN. As before, this signal can be gated so that the control signal is blocked until the input signals are stable, as described above in FIG. 7.

According to this embodiment, however, a number of gating circuits 79₀ to 79_{N} are connected in the output path of each multiplexer 59₀ to 59_{N}. In other words, the glitches are suppressed on the data lines after they have been selected by the multiplexers 59₀ to 59_{N}. This embodiment has the advantage of requiring less gating circuits than the second embodiment shown in FIG. 8, and prevents any power dissipation due to glitches caused by the bus, and variations introduced by the multiplexers 59₀ to 59_{N}.

It is noted that any combination of the three embodiments described above is also possible. For example, if the embodiment described in FIG. 7 is combined with the embodiment described in FIG. 9, this arrangement reduces power in the multiplexer part and prevents transitions (for example due to error correction) from appearing at the output. In a similar manner, if the embodiment described in FIG. 7 is combined with the embodiment described in FIG. 8, this arrangement removes the spread in transition delays at the output, and also prevents transitions (for example due to error correction) from appearing at the output. Other combinations are also possible.

The invention can also be used with other types of decoding circuits.

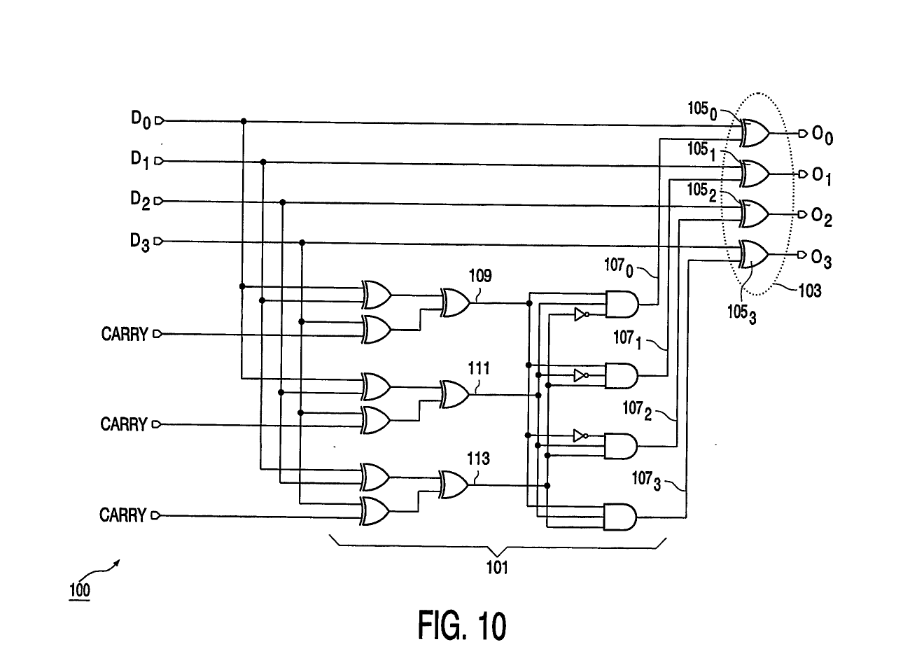

FIG. 10 shows a traditional hamming decoder 100 for a (7,4) optimal hamming code. The decoder 100 receives input data signals D₀, D₁, D₂, D₃ which are decoded by a decoding circuit 101. The decoder 100 also comprises a correcting circuit 103, which receives the output of the decoding circuit 101. For the 4-bit hamming decoder shown, the decoding circuit 101 comprises three parity trees that generate three parity signals 109, 111, 113, respectively. The parity signals 109, 111, 113 are passed to a syndrome decoder, which generates control signals 107₀, 107₁, D107, 107₃ for controlling the correcting circuit 103. Preferably, the correcting circuit 103 comprises a plurality of exclusive OR gates 105₀, 105₁, 105₂, 105₃, each exclusive OR gate receiving one of the input signals D₀, D₁, D₂, D₃ and a respective one of the control signal 107₀, 107₁, D107, 107₃. As described earlier in the application, since the input data signals have different flight times, the correcting circuit 103 can switch erroneously between correcting and non-correcting modes of operation, thereby causing undesired glitches.

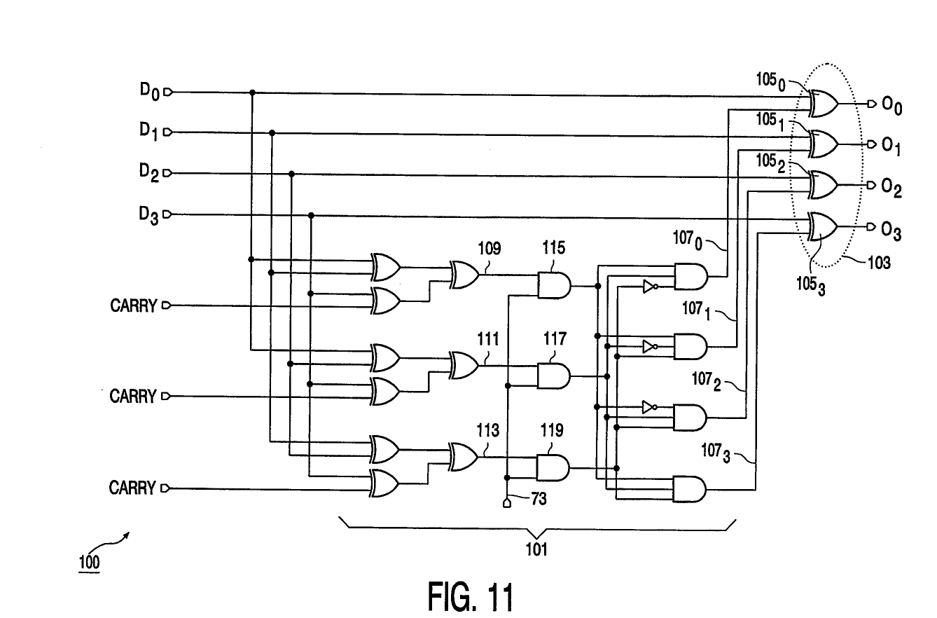

FIG. 11 shows an improved hamming decoder 100 according to the present invention. The decoder 100 receives input data signals D₀, D₁, D₂, D₃ which are decoded by a decoding circuit 101. The decoder 100 also comprises a correcting circuit 103, which receives the output of the decoding circuit 101. The decoding circuit 101 comprises three parity trees that generate three parity signals 109, 111, 113, respectively. The parity signals 109, 111, 113 are passed to a syndrome decoder, which generates control signals 107₀, 107₁, D107, 107₃ for controlling the correcting circuit 103. Preferably, the correcting circuit 103 comprises a plurality of exclusive OR gates 105₀, 105₁, 105₂, 105₃, each exclusive OR gate receiving one of the input signals D₀, D₁, D₂, D₃ and a respective one of the control signal 107₀, 107₁, D107, 107₃. However, according to this embodiment, the hamming decoder further comprises one or more gating circuits 115, 117, 119. The gating circuits 115, 117, 119 are placed in the path of the circuit that generates the control signals, thereby preventing the generation of unwanted glitches.

Preferably, the gating circuits 115, 117 and 119 are placed between the parity trees and the syndrome decoder. For example, gating circuit 115 receives the first parity signal 109 and the gating control signal 73. Gating circuit 117 receives the second parity signal 111 and the gating control signal 73, while gating circuit 119 receives the third parity signal 113 and the gating control signal 73. In this manner, the parity signals 109, 111, 113 are blocked from passing to the syndrome decoder until a predetermined time controlled by the gating control signal 73. Preferably, the gating control signal is triggered after all of the input signals are stable. Alternatively, the gating control signal 73 can be triggered after the majority of the input signals are stable. Although this alternative only allows partial reduction in glitches, and hence only partial power reduction, this solution has less of a speed penalty.

The embodiment described above provides a hamming decoder that has a reduced number of glitches and hence a reduced power consumption. For the (7, 4) optimal hamming decoder described in the embodiment, it is noted that three gating circuits were provided for the three parity trees. For larger wordsizes, however, hamming decoders become more attractive since the number of additional parity trees is proportional to the log of the number of data bits. Hence, for 32 data bits, only six parity trees and thus six gating circuits are required.

Although the preferred embodiments have been described in relation to a dual-rail decoder circuit and a hamming decoder, it will be appreciated that the invention is also applicable to other types of decoder circuits. The invention is also suitable for use with non-fault tolerant codes.

In addition, although the preferred embodiments of the invention describe the gating circuit as an AND gate, it will be appreciated that other selection logic or latch circuits may be used for this purpose.

Furthermore, although some of the embodiments have been described with reference to a decoder circuit receiving a predetermined number data signals, it will be appreciated that the communication can work with any number of data signals.

The invention described above has the advantage of reducing power consumption in a decoder circuit, by reducing the number of glitches generated in the decoder circuit.

It is also noted that, although the preferred embodiments refer to reducing power consumption by generating the gating control signal 73 at a predetermined time corresponding to when all of the input data signals are stable, alternatively, the gating control signal 73 can be triggered after only some of the input signals are deemed to be stable. Although this alternative only allows partial reduction in glitches, and hence only partial power reduction, this solution has less of a speed penalty.

It is also noted that, although the preferred embodiments refer to the gating control signal being generated from a delayed version of the system clock, the gating control signal may also be generated using other methods, for example using the input data and/or parity bits. This alternative provides a self-timed solution.

1. A decoder circuit for a communication bus, the decoder circuit receiving a plurality of data signals from the communication bus, the data signals being susceptible of being received at different times, wherein the decoder circuit comprises:
a correction circuit for correcting one or more of the input signals;
a control signal for controlling the correction circuit;
a gating circuit, the gating circuit arranged in the path of the control signal; and
a gating control signal for controlling the gating circuit such that the control signal for controlling the correction circuit is blocked until a predetermined time.

2. A decoder circuit as claimed in claim 1, further comprising a parity circuit for generating a parity signal using the input data signals, the parity signal being used to generate said control signal for controlling the correction circuit.

3. A decoder circuit as claimed in claim 2, wherein the correction circuit comprises a plurality of multiplexers, each multiplexer receiving an input data signal, and a copy of the input data signal, from the communication bus;
a comparison circuit for comparing the parity signal generated by the parity circuit with a parity signal received from the communication bus, the comparison circuit providing the control signal for controlling the plurality of multiplexers to output either the input data signal or the copy of the input data signal.

4. A decoder circuit as claimed in claim 3, wherein the gating circuit is located in the path of the control circuit such that it receives the output of the comparison circuit, and provides the control signal for controlling the plurality of multiplexers.

5. A decoder circuit as claimed in claim 2, further comprising a gating circuit provided in the path of each input data signal and each copy of the input data signal, and wherein the plurality of gating circuits are controlled by the gating control signal.

6. A decoder circuit as claimed in claim 3, further comprising a gating circuit provided in the output path of each multiplexer, and wherein the plurality of gating circuits are controlled by the gating control signal.

7. A decoder as claimed in claim 2, wherein the decoder is a dual-rail decoder.

8. A decoder circuit as claimed in claim 1, further comprising:
a plurality of parity circuits, the parity circuits generating a plurality of parity signals from the input data signals;
means for generating a plurality of control signals using the parity signals, the control signals being used to control the correction circuit;
wherein a gating circuit is provided in the path between each parity signal and the means for generating the plurality of control signals.

9. A decoder circuit as claimed in claim 8, wherein the correction circuit comprises a plurality of XOR gates, each XOR gate receiving an input data signal from the communication bus, and a control signal from the means for generating control signals.

10. A decoder circuit as claimed in claim 9, wherein the means for generating control signals is a syndrome decoder.

11. A decoder circuit as claimed in claim 8, wherein the decoder is a hamming decoder.

12. A decoder circuit as claimed in claim 1, wherein the gating control signal is arranged to block the or each control signal from passing to the correction circuit until one or more of the input data signals have become stable.

13. A decoder circuit as claimed in claim 1, wherein the gating control signal is arranged to block the or each control signal from passing to the correction circuit until all of the input data signals have become stable.

14. A decoder circuit as claimed in claim 1, wherein the gating control signal is a delayed version of a system clock signal.

15. A decoder circuit as claimed in claim 1, wherein the gating control signal is generated from the input data and/or parity bits.

16. A decoder circuit as claimed in claim 1, wherein the gating circuit is an AND gate.

17. A decoder circuit as claimed in
claim 1, wherein the gating circuit is a latch.

18. A method of reducing power consumption in a decoder circuit for a communication bus, the decoder circuit receiving a plurality of data signals from the communication bus, the data signals being susceptible of being received at different times, wherein the decoder circuit comprises a correction circuit for correcting one or more of the input signals and a control signal for controlling the correction circuit,
wherein the method comprises the steps of providing a gating circuit in the path of the control signal, and controlling the gating circuit with a gating control signal, such that the control signal for controlling the correction circuit is blocked until a predetermined time.

19. A method as claimed in claim 18, wherein a parity circuit is provided for generating a parity signal using the input data signals, the parity signal being used to generate said control signal for controlling the correction circuit.

20. A method as claimed in claim 19, wherein the correction circuit comprises a plurality of multiplexers, each multiplexer receiving an input data signal, and a copy of the input data signal, from the communication bus, and a comparison circuit for comparing the parity signal generated by the parity circuit with a parity signal received from the communication bus, the comparison circuit providing the control signal for controlling the plurality of multiplexers to output either the input data signal or the copy of the input data signal.

21. A method as claimed in claim 20, further comprising the step of locating the gating circuit in the path of the control circuit such that it receives the output of the comparison circuit, and provides the control signal for controlling the plurality of multiplexers.

22. A method as claimed in claim 19 further comprising the step of providing a gating circuit in the path of each input data signal and each copy of the input data signal, and controlling the plurality of gating circuits with the gating control signal.

23. A method as claimed in claim 20, further comprising the step of providing a gating circuit in the output path of each multiplexer, and controlling the plurality of gating circuits with the gating control signal.

24. A method as claimed in claim 19, wherein the decoder is a dual-rail decoder.

25. A method as claimed in claim 18, further comprising the steps of:
providing a plurality of parity circuits, the parity circuits generating a plurality of parity signals from the input data signals;
providing means for generating a plurality of control signals using the parity signals, the control signals being used to control the correction circuit; and
providing a gating circuit in the path between each parity signal and the means for generating the plurality of control signals.

26. A method as claimed in claim 25, wherein the correction circuit comprises a plurality of XOR gates, each XOR gate receiving an input data signal from the communication bus, and a control signal from the means for generating control signals.

27. A method as claimed in claim 26, wherein the means for generating control signals is a syndrome decoder.

28. A method as claimed in claim 25, wherein the decoder is a hamming decoder.

29. A method as claimed in claim 18, wherein the gating control signal is arranged to block the or each control signal from passing to the correction circuit until one or more of the input data signals have become stable.

30. A method as claimed in claim 18, wherein the gating control signal is arranged to block the or each control signal from passing to the correction circuit until all of the input data signals have become stable.

31. A method as claimed in claim 18, wherein the gating control signal is a delayed version of a system clock signal.

32. A method as claimed in claim 18, wherein the gating control signal is generated from the input data and/or parity bits.

33. A method as claimed in claim 18, wherein the gating circuit is an AND gate.

34. A method as claimed in claim 18, wherein the gating circuit is a latch.
